(19) United States
(12) Patent Application Publication
(10) Pub. No.: US 2026/0141963 A1
(43) Pub. Date: May 21, 2026

(54) MEMORY DEVICE, CURRENT-TO-VOLTAGE CONVERTER AND DATA LINE PRE-CHARGE METHOD

(71) Applicant: Winbond Electronics Corp., Taichung City (TW)

(72) Inventor: Chung-Zen Chen, HsinChu (TW)

(73) Assignee: Winbond Electronics Corp., Taichung City (TW)

(21) Appl. No.: 19/396,358

(22) Filed: Nov. 21, 2025

(30) Foreign Application Priority Data
Nov. 21, 2024 (TW) 113144815

(51) Int. Cl. G11C 16/32; G11C 5/14; G11C 16/26

(52) U.S. Cl. CPC G11C 16/32; G11C 5/145; G11C 16/26

(57) ABSTRACT

A memory device, a current-to-voltage converter, and a data line pre-charge method are provided. The current-to-voltage converter includes a first pre-charge circuit, a second pre-charge circuit, and a pull-down circuit. The first pre-charge circuit is configured to pre-charge a voltage on a data line to a preset voltage according to a sensing enable signal at a first logic level during a pre-charge period of a data sensing operation; The second pre-charge circuit is configured to generate a feedback voltage according to the voltage on the data line and pull up the voltage on the data line according to the feedback voltage during the pre-charge period. The pull-down circuit is configured to discharge the data line according to the sensing enable signal at a second logic level.

### CROSS-REFERENCE TO RELATED APPLICATION

This application claims the priority benefit of Taiwan application serial no. 113144815, filed on November 21, 2024. The entirety of the above-mentioned patent application is hereby incorporated by reference herein and made a part of this specification.

### BACKGROUND

### Technical Field

The disclosure relates to a memory device, and in particular, to a memory device, a current-to-voltage converter, and a data line pre-charge method capable of improving the data pre-charge speed.

### Description of Related Art

During a read or verification operation of a flash memory, a comparator is used to determine whether the selected memory cell is in a programmed state (e.g., a logic value "0") or in an erased state (e.g., a logic value "1"). Prior to this, the data lines coupled to the memory cells need to be pre-charged. To be specific, the flash memory has data lines coupled to the memory cells, and the data lines are coupled to a current-to-voltage converter. During the early stage of the read or verification operation, including the data line pre-charge period, the current-to-voltage converter may convert the current read from the selected memory unit into a sensing voltage signal VSA and output it to the comparator. After that, the comparator may compare the sensing voltage signal VSA with a reference voltage signal VSAR from a reference memory unit and output the comparison result. However, if the data line is pre-charged excessively high, memory cell interference may occur, leading to failure of the read or verification operation. Therefore, to ensure a certain product lifetime for the flash memory, the voltage on the pre-charged data line is controlled within a predetermined range. However, this design may result in reduced pre-charge speed. As the capacity of flash memory increases, this problem will become more severe. To improve the operating speed of electronic devices, enhancing the read or verify speed of flash memory is one of the key objectives. Therefore, it is necessary to improve the current-to-voltage converter to reduce the required time for data line pre-charging.

### SUMMARY

The disclosure provides a memory device, a current-to-voltage converter, and a data line pre-charge method for improving the pre-charge rate of the data line voltage.

The disclosure provides a current-to-voltage converter including a first pre-charge circuit, a second pre-charge circuit, and a pull-down circuit. The first pre-charge circuit is coupled to a data line and is configured to pre-charge a voltage on the data line to a preset voltage according to a sensing enable signal at a first logic level during a pre-charge period of a data sensing operation. The second pre-charge circuit is coupled to the data line and is configured to generate a feedback voltage according to the voltage on the data line and pull up the voltage on the data line according to the feedback voltage during the pre-charge period. The pull-down circuit is coupled to the data line and is configured to discharge the data line according to the sensing enable signal at a second logic level. The data line is coupled to a memory cell.

The disclosure further provides a data line pre-charge method, and the method includes the following steps. During a pre-charge period of a data sensing operation, a first pre-charge circuit receives a sensing enable signal at a first logic level and pre-charges a voltage on the data line to a preset voltage. A second pre-charge circuit receives the voltage on the data line to generate a feedback voltage and pulls up the voltage on the data line according to the feedback voltage during the pre-charge period. When the sensing enable signal is at a second logic level, a pull-down circuit discharges the data line.

The disclosure further provides a memory device including a memory cell array, a plurality of first current-to-voltage converters, and a second current-to-voltage converter. The memory cell array includes a plurality of dummy memory cells and a plurality of normal memory cells. The dummy memory cells are coupled to a dummy global bit line coupled to a dummy data line. The normal memory cells are coupled to a plurality of global bit lines, and each of the global bit lines is coupled to a data line. Each of the first current-voltage converters is coupled to the data line and controlled by a common feedback voltage. The second current-to-voltage converter includes a first pre-charge circuit, a second pre-charge circuit, and a pull-down circuit. The first pre-charge circuit is coupled to a data line and is configured to pre-charge a voltage on the data line to a preset voltage according to a sensing enable signal at a first logic level during a pre-charge period of a data sensing operation. The second pre-charge circuit is coupled to the data line and is configured to generate a feedback voltage according to the voltage on the data line and pull up the voltage on the data line according to the feedback voltage during the pre-charge period. The pull-down circuit is coupled to the data line and is configured to discharge the data line according to the sensing enable signal at a second logic level. The data line is coupled to a memory cell.

To sum up, in the present disclosure, the current-to-voltage converter generates the feedback voltage according to the voltage of the data line during the pre-charge period of the data sensing operation and pulls up the voltage on the data line to the preset voltage according to the feedback voltage. Further, during the pre-charge period of the data sensing operation, the first pre-charge circuit can synchronously pull up the voltage on the data line to the preset voltage according to the pre-charge control signal. In this way, in the disclosure, during the pre-charge period of the data sensing operation, the current-to-voltage converter can quickly pull up the voltage on the data line to the preset voltage, such that the working performance of the memory device is improved.

### BRIEF DESCRIPTION OF THE DRAWINGS

FIG. 1 is a schematic diagram illustrating a current-to-voltage converter according to an embodiment of the disclosure.

FIG. 2 is a schematic diagram illustrating circuits of a current-to-voltage converter according to an embodiment of the disclosure.

FIG. 3A and FIG. 3B are schematic diagrams illustrating pre-charge control signal generating circuits according to different embodiments of the disclosure.

FIG. 4 is a waveform diagram illustrating an operation of the current-to-voltage converter according to an embodiment of the disclosure.

FIG. 5 is a schematic diagram illustrating a current-to-voltage converter according to another embodiment of the disclosure.

FIG. 6 is an operation waveform diagram illustrating a current-to-voltage converter according to another embodiment of the disclosure.

FIG. 7 is a schematic diagram of illustrating a memory device according to an embodiment of the disclosure.

FIG. 8 is a schematic diagram illustrating a second current-to-voltage converter according to an embodiment of the disclosure.

FIG. 9 is a schematic diagram illustrating a first current-to-voltage converter according to an embodiment of the disclosure.

FIG. 10 is a flow chart illustrating a data line pre-charge method according to an embodiment of the disclosure.

### DESCRIPTION OF THE EMBODIMENTS

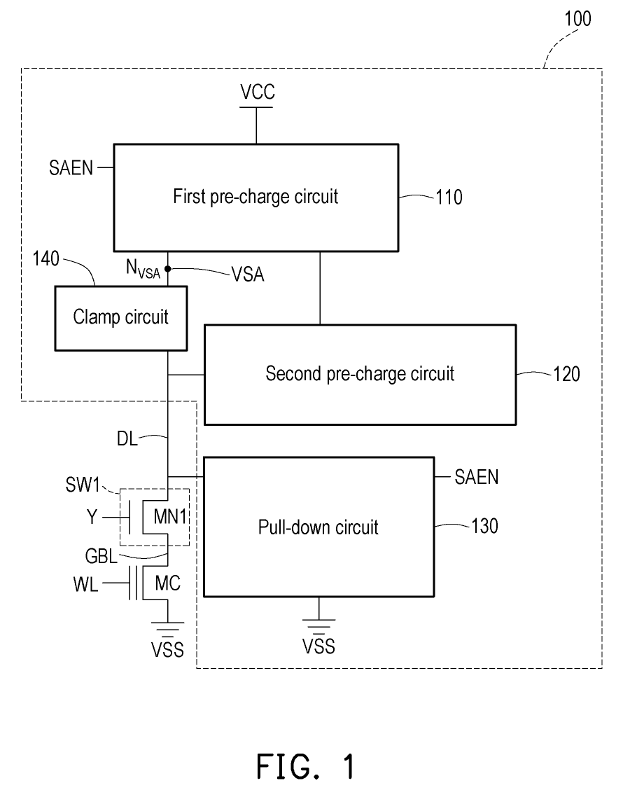

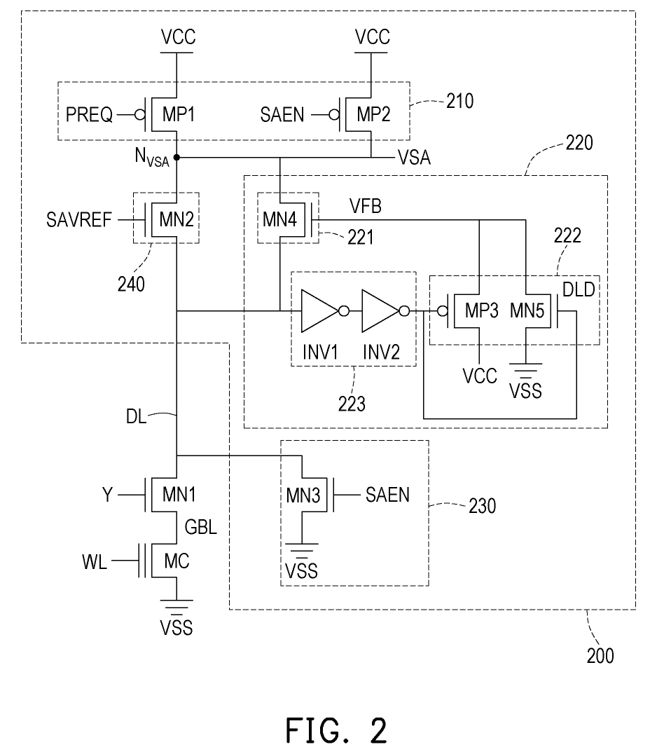

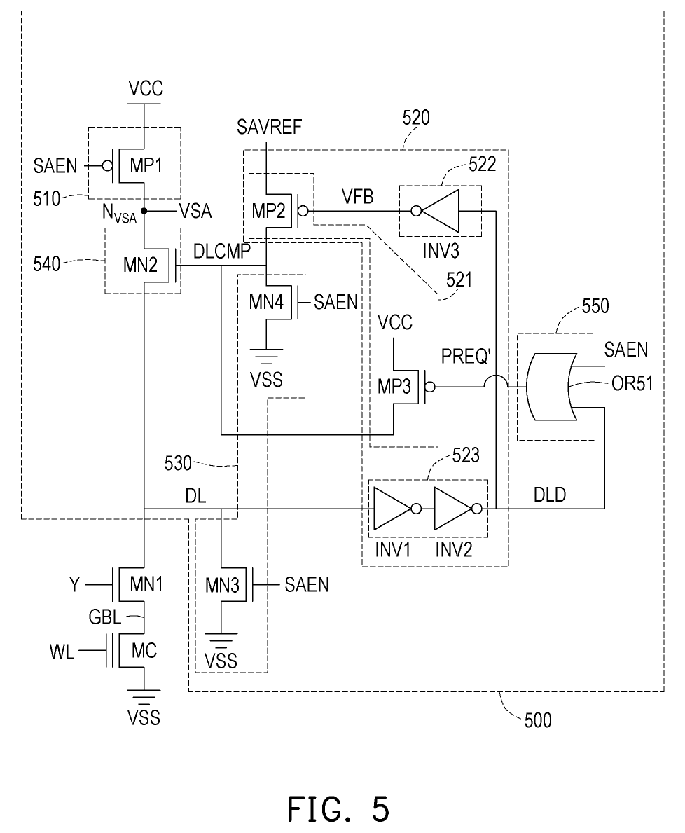

With reference to FIG. 1, a current-to-voltage converter 100 according to an embodiment of the disclosure is configured to pre-charge a data line DL during a pre-charge period of a data sensing operation and output a sensing voltage signal VSA. Generally, the current-to-voltage converter 100 of the disclosure includes a first pre-charge circuit 110, a second pre-charge circuit 120, and a pull-down circuit 130. The first pre-charge circuit 110 receives a power supply voltage VCC and is coupled to the data line DL. The first pre-charge circuit 110 is configured to pre-charge a voltage on the data line DL to a preset voltage according to the power supply voltage VCC and a sensing enable signal SAEN at a first logic level during the pre-charge period of the data sensing operation. The data line DL may be coupled to a global bit line GBL of a memory cell MC through a switch SW1. The switch SW1 includes, for example, a transistor MN1 and is controlled by a selection signal Y, but the disclosure is not limited thereto. The memory cell MC is controlled by a bit line signal WL. The second pre-charge circuit 120 is coupled to the first pre-charge circuit 110 and the data line DL. The second pre-charge circuit 120 is configured to generate a feedback voltage VFB (shown in FIG. 2 and FIG. 5) according to the voltage on the data line DL, and pre-charge the voltage on the data line DL to the preset voltage according to the feedback voltage VFB during the pre-charge period of the data sensing operation. Further, the pull-down circuit 130 is coupled to the data line DL and is configured to discharge the data line DL in a standby mode according to the sensing enable signal SAEN at a second logic level. The data sensing operation may be a read or verification operation.

In this embodiment, the sensing enable signal SAEN at a low logic level is used to indicate that the data sensing operation corresponding to the current-to-voltage converter 100 has been executed. A pre-charge control signal PREQ is used to indicate that the data sensing operation has entered the pre-charge period. Herein, the pre-charge period occurs in the early stage of the data sensing operation.

In a preferred embodiment, a pre-charge speed provided by the second pre-charge circuit 120 may be greater than a pre-charge speed provided by the first pre-charge circuit 110. Detailed description is provided in the following embodiments.

In this embodiment, the current-to-voltage converter 100 may include a clamp circuit 140 coupled between the first pre-charge circuit 110 and the data line DL and is configured to output a sensing voltage signal VSA at a sensing voltage node N_{VSA} between the clamp circuit 140 and the first pre-charge circuit 110. The first pre-charge circuit 110 may provide a first pre-charge path to the data line DL. The second pre-charge circuit 120 may be configured to detect the voltage on the data line DL and generate the feedback voltage VFB to provide a second pre-charge path to the data line DL, so that the voltage on the data line DL may be accelerated to pull up. When the voltage on the data line DL is pulled up to near the preset voltage, the second pre-charge circuit 120 may cut off the aforementioned second pre-charge path according to the feedback voltage VFB. As such, during the pre-charge period of the data sensing operation, the current-to-voltage converter 100 may provide multiple pre-charge paths to pull up the voltage on the data line DL, so as to accelerate the speed of pulling up the voltage on the data line DL to the preset voltage, and the data sensing operation is thus accelerated.

To be specific, with reference to FIG. 2, a first pre-charge circuit 210 of a current-to-voltage converter 200 in this embodiment may include transistors MP1 and MP2 coupled in parallel between the power supply voltage VCC and the sensing voltage node N_{VSA} and respectively controlled by the pre-charge control signal PREQ and the sensing enable signal SAEN, but the disclosure is not limited thereto.

A clamp circuit 240 may include, for example, a transistor MN2, but the disclosure is not limited thereto. The transistor MN2 is coupled in series with the transistor MP1 between the power supply voltage VCC and the data line DL. A first terminal of the transistor MN2 is coupled to the sensing voltage node, a second terminal of the transistor MN2 is coupled to the data line DL, and a control terminal of the transistor MN2 may receive a reference voltage SAVREF. In this embodiment, the clamp circuit 240 is configured to clamp the voltage on the data line DL to be substantially not greater than the preset voltage during a voltage pull-up operation according to the reference voltage SAVREF, so that the product lifetime of a memory device is improved.

In detail, during the pre-charge period of the data sensing operation, the transistors MP1 and MP2 of the first pre-charge circuit 210 may be turned on respectively according to the pre-charge control signal PREQ and the sensing enable signal SAEN, and the transistor MN2 is controlled through the reference voltage SAVREF. In this way, the power supply voltage VCC is allowed to flow through the transistors MP1 and MP2 and is provided to the data line DL after being clamped by the clamp circuit 240, so as to pre-charge the data line DL to the preset voltage.

To be specific, a second pre-charge circuit 220 of the current-to-voltage converter 200 in this embodiment may include a driving control element 221, a feedback voltage generating element 222, and a buffer 223. The buffer 223 is configured to generate a feedback voltage control signal DLD according to the voltage on the data line DL. The feedback voltage generating element 222 is configured to be controlled by the feedback voltage control signal DLD and generate the feedback voltage VFB according to the power supply voltage VCC and a reference ground voltage VSS. The driving control element 221 is coupled in parallel with the clamp circuit 240 between the sensing voltage node N_{VSA} and the data line DL and is controlled by the feedback voltage VFB to determine the on/off state of the second pre-charge path.

In this embodiment, the driving control element 221 may include a transistor MN4, the feedback voltage generating element 222 may include transistors MP3 and MN5, and the buffer 223 may include inverters INV1 and INV2 connected in series, but the disclosure is not limited thereto. A first terminal of the transistor MN4 is coupled to the sensing voltage node N_{VSA}, a second terminal is coupled to the data line DL, and a control terminal is coupled to first terminals of transistors MP3 and MN5. An input terminal of the inverter INV1 (i.e., an input terminal of the buffer 223) is coupled to the data line DL, an output terminal of the inverter INV1 is coupled to an input terminal of the inverter INV2, and an output terminal of the inverter INV2 (i.e., an output terminal of the buffer 223) is coupled to control terminals of transistors MP3 and MN5.

The transistors MP3 and MN5 have opposite conduction polarities, and in this embodiment, the transistor MP3 is a P-type transistor, while the transistor MN5 is an N-type transistor. A second terminal of the transistor MP3 receives the power supply voltage VCC. A second terminal of the transistor MN5 receives the reference ground voltage VSS. The transistors MP3 and MN5 are controlled by the voltage on the data line DL to generate the feedback voltage VFB at their first terminals.

In terms of operational details, the inverters INV1 and INV2 are used to delay the voltage on the data line DL and digitize the voltage on the data line DL to generate the feedback voltage control signal DLD, which is then transmitted to the control terminals of the transistors MP3 and MN5. When the data line DL has a relatively low voltage value, the control terminals of the transistors MP3 and MN5 receive a logical low voltage and are turned on and off respectively. The turned-on transistor MP3 can pull up the feedback voltage VFB according to the power voltage VCC. In this way, the transistor MN4 may be turned on according to the feedback voltage VFB having a relatively high voltage value and provide the second pre-charge path between the sensing voltage node N_{VSA} and the data line DL.

According to this embodiment, during the pre-charge period of the data sensing operation, the voltage on the data line DL may be pulled up by the clamp circuit 240. Further, by connecting the driving control element 221 between the sensing voltage node N_{VSA} and the data line DL in parallel with the clamp circuit 240, the time required for the voltage on the data line DL to reach the preset voltage can be reduced, thereby increasing the efficiency of the data sensing operation.

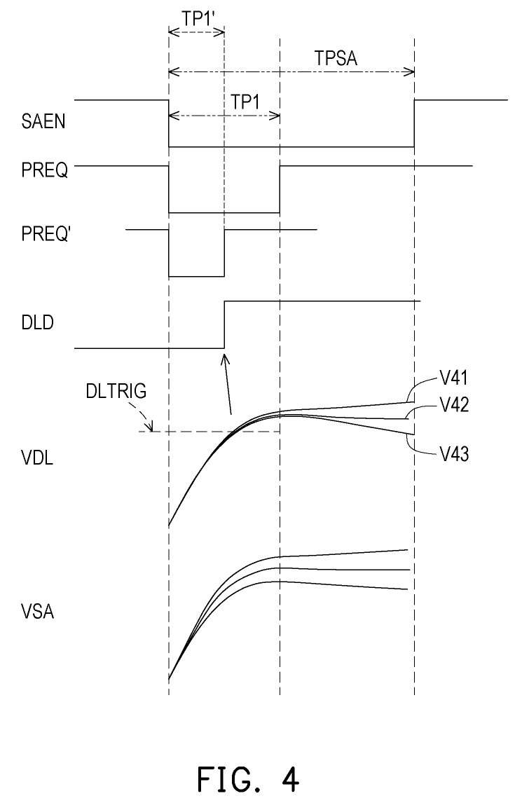

When the voltage on the data line DL reaches a trigger voltage DLTRIG (as shown in FIG. 4), the feedback voltage control signal DLD output from the inverter INV2 may switch to a logic high level. The control terminals of the transistors MP3 and MN5 may be supplied with the logic high level, resulting in the deactivation of the transistor MP3 and activation of the transistor MN5. Consequently, the feedback voltage VFB is pulled down, causing the transistor MN4 to turn off. This action prevents the second pre-charge circuit 220 from elevating the voltage on the data line DL, effectively closing the second pre-charge path.

The pull-down circuit 230 may include the transistor MN3, but the disclosure is not limited thereto. The transistor MN3 is coupled between the data line DL and the reference ground voltage VSS and is controlled by the sensing enable signal SAEN. In this embodiment, during the data sensing operation, according to the sensing enable signal SAEN at a low logic level, the transistor MN3 is turned off. When the data sensing operation is completed, the transistor MN3 may be turned on according to the sensing enable signal SAEN at a high logic level and may pull down the voltage on the data line DL according to the reference ground voltage VSS.

In addition, based on the fact that transistors MN3 and MP2 have different conductive polarities, when transistor MN3 is turned on, the transistor MP2 is turned off, and when transistor MN3 is turned off, transistor MP2 may be turned on.

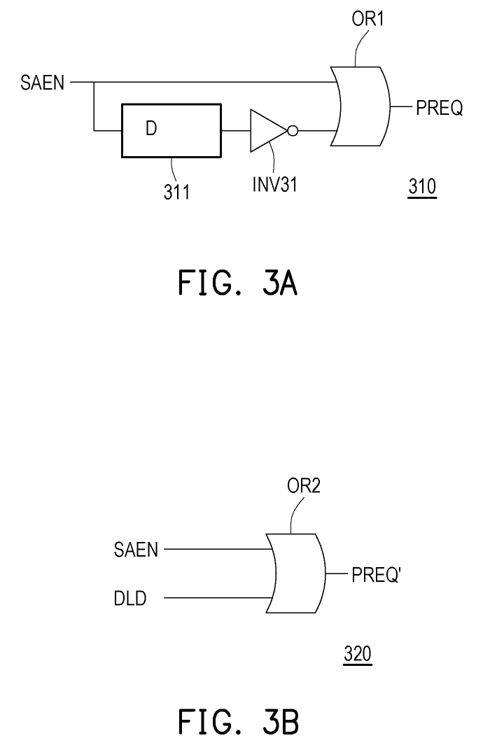

In some embodiments, the current-to-voltage converter 100 may also include a pre-charge control signal generating circuit 310 or 320. In FIG. 3A, the pre-charge control signal generating circuit 310 includes a delay device 311, an OR gate OR1, and an inverter INV31. The delay device 311 receives the sensing enable signal SAEN and delays the sensing enable signal SAEN according to a delay value D. One input terminal of the OR gate OR1 directly receives the sensing enable signal SAEN, while the other input terminal of the OR gate OR1 receives the delayed and inverted signal of the sensing enable signal SAEN through the inverter INV1. An output terminal of the OR gate OR1 then generates the pre-charge control signal PREQ.

The pre-charge control signal generating circuit 310 is a one-shot circuit and is used to generate the pre-charge control signal PREQ with a negative pulse based on a falling edge of the input sensing enable signal SAEN. Herein, the delay value D provided by the delay device 311 may be used to determine a width of the negative pulse of the pre-charge control signal PREQ.

In FIG. 3B, the pre-charge control signal generating circuit 320 includes an OR gate OR2, which receives the sensing enable signal SAEN and the feedback voltage control signal DLD. In the embodiment of FIG. 2, the feedback voltage control signal DLD corresponds to the voltage on the data line DL. In other words, when the data sensing operation is activated (the sensing enable signal SAEN is at a logic low level) and when the data line DL has a relatively low voltage value, the OR gate OR2 may generate a pre-charge control signal PREQ' at a logic low level.

FIG. 4 is a waveform diagram illustrating an operation of the current-to-voltage converter according to an embodiment of the disclosure. With reference to FIG. 2, FIG. 3A, FIG. 3B, and FIG. 4 together, when the data sensing operation is activated, the sensing enable signal SAEN may be pulled down to a logic low level, for example, during a pre-charge period TPSA of the data sensing operation. The pre-charge control signal PREQ (or PREQ') may provide a negative pulse corresponding to the sensing enable signal SAEN. Further, through the sensing enable signal SAEN at the logic low level and the pre-charge control signal PREQ (or PREQ'), the first pre-charge circuit 210 and the second pre-charge circuit 220 may pull up a voltage VDL on the data line DL during an initial pre-charge period TP1 (or TP1') of the pre-charge period TPSA of the data sensing operation.

Specifically, when the voltage VDL on the data line DL is raised above the trigger voltage DLTRIG, the feedback voltage control signal DLD may switch to a logic high level to turn off the second pre-charge path, thereby reducing the upward slope of the voltage VDL on the data line DL.

When the pre-charge control signal PREQ (or PREQ') switches to a logic high level, the initial pre-charge period TP1 (or TP1') ends. The current-to-voltage converter 200 continues to pre-charge the data line DL through the transistors MP2 and MN2. The voltage VDL on the data line DL may be offset from a preset voltage value according to the state of the threshold voltage of the memory cell MC. Compared to a voltage V42 on the data line coupled to a reference memory cell, if the memory cell MC is a programmed memory cell, the voltage VDL may be shifted upward to a voltage V41, and if the memory cell MC is an erased memory cell, the voltage VDL may be shifted downward to a voltage V43.

It should be noted that, based on the variation of the voltage VDL on the data line DL, the sensing voltage signal VSA output from the sensing voltage node N_{VSA} may also exhibit corresponding variation. The sensing voltage signal VSA is provided to a comparator in the memory device, and the read data of the memory cell is determined by comparing the sensing voltage signal VSA with a reference voltage signal VSAR. Any known circuit may be used to constitute the comparator.

In the above embodiments, the clamp circuit 240 is controlled by the reference voltage SAVREF, and the driving control element 221 is arranged in parallel with the clamp circuit 240 between the sensing voltage node N_{VSA} and the data line DL, but the disclosure is not limited thereto. With reference to FIG. 5 next, according to another embodiment of the disclosure, a current-to-voltage converter 500 includes a first pre-charge circuit 510, a second pre-charge circuit 520, a pull-down circuit 530, a clamp circuit 540, and a pre-charge control signal generating circuit 550.

The first pre-charge circuit 510 is configured to provide the power supply voltage VCC to the sensing voltage node N_{VSA} during the pre-charge period according to the sensing enable signal SAEN at a low logic level. The first pre-charge circuit 510 may include the transistor MP1, which has a first terminal receiving the power supply voltage VCC, a control terminal receiving the sensing enable signal SAEN, and a second terminal coupled to the sensing voltage node N_{VSA}.

The second pre-charge circuit 520, coupled to the data line DL, may include a driving control element 521, a feedback voltage generating element 522, and a buffer 523. The buffer 523 is configured to generate the feedback voltage control signal DLD according to the voltage on the data line DL and provide the feedback voltage control signal DLD to the feedback voltage generating element 522 and the pre-charge control signal generating circuit 550.

The clamp circuit 540 is coupled between the sensing voltage node N_{VSA} and the data line DL and is controlled by a clamp control signal DLCMP. The clamp circuit 540 may include the transistor MN2.

The driving control element 521 provides the clamp control signal DLCMP to the clamp circuit 540 according to the feedback voltage VFB and the pre-charge control signal PREQ'. The feedback voltage VFB and the pre-charge control signal PREQ' may be generated according to the voltage on the data line DL. Thus, the conduction state of the clamp circuit 540 can be controlled according to the voltage on the data line DL to regulate the pre-charge of the data line DL. In this embodiment, during an early stage of the pre-charge period, the driving control element 521 may provide the clamp circuit 540 with a clamp control signal DLCMP having a higher driving strength based on the pre-charge control signal PREQ'. This increases the pre-charge speed. During the later stage of the pre-charge period, when the voltage on the data line DL reaches the trigger voltage DLTRIG, the driving control element 521 may provide the clamp circuit 540 with a clamp control signal DLCMP having a lower driving strength based on the feedback voltage VFB. This prevents overcharging of the data line DL.

In this embodiment, the driving control element 521 may include transistors the MP2 and MP3 coupled to different voltages to provide different driving strengths to the clamp circuit 540. The transistor MP2 receives the reference voltage SAVREF and provides the clamp control signal DLCMP to the clamp circuit 540 controlled by the feedback voltage VFB. The transistor MP3 receives the power supply voltage VCC and provides the clamp control signal DLCMP to the clamp circuit 540 controlled by the pre-charge control signal PREQ'. The reference voltage SAVREF is less than the power supply voltage VCC.

The inverters INV1 and INV2 are connected in series to form the buffer 523. The input terminal of the inverter INV1 (which is an input terminal of the buffer 523) is coupled to the data line DL, and the output terminal of the inverter INV2 (which is an output terminal of the buffer 523) generates the feedback voltage control signal DLD. The pre-charge control signal generating circuit 550 receives the feedback voltage control signal DLD and the sensing enable signal SAEN, and performs a logical operation on the two signals to generate the pre-charge control signal PREQ'. In this embodiment, the pre-charge control signal generating circuit 550 includes an OR gate OR51, which performs a logical OR operation on the feedback voltage control signal DLD and the sensing enable signal SAEN to generate the pre-charge control signal PREQ'.

The feedback voltage generating element 522 is configured to generate the feedback voltage VFB according to the voltage on the data line DL. In this embodiment, the feedback voltage generating element 522 may include an inverter INV3. The inverter INV3 receives the feedback voltage control signal DLD from the buffer 523 and inverts the feedback voltage control signal DLD to generate the feedback voltage VFB.

The pull-down circuit 530 is configured to discharge the data line DL according to the sensing enable signal SAEN at a high logic level. In this embodiment, the pull-down circuit 530 may include transistors the MN3 and MN4. The transistor MN3 is coupled between the data line DL and the reference ground voltage VSS and is controlled by the sensing enable signal SAEN. The transistor MN4 is coupled between the control terminal of the clamp circuit 540 and the reference ground voltage VSS and is controlled by the sensing enable signal SAEN. To be specific, the second terminal of the transistor MP2 may be coupled to the second terminal of the transistor MN4. In this embodiment, during the data sensing operation, the transistors MN3 and MN4 are turned off according to the sensing enable signal SAEN at a low logic level. When the data sensing operation ends, the transistors MN3 and MN4 may be turned on according to the sensing enable signal SAEN at a high logic level and pull down the voltage on the data line DL and turn off the first pre-charge circuit 510 and the second pre-charge circuit 520 according to the reference ground voltage VSS. The power consumption of the current-to-voltage converter 500 in the standby mode may thus be reduced.

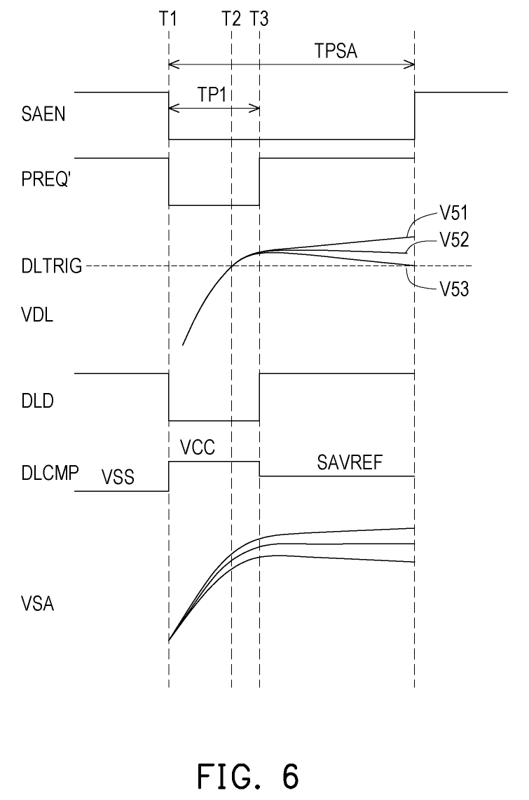

Regarding the operational details of the current-to-voltage converter 500, please refer to the operation waveform diagram illustrated in FIG. 6. Initially (before the pre-charge period TPSA), the sensing enable signal SAEN is at a logic high level. Correspondingly, the pre-charge control signal PREQ' is also at a logic high level. Through the pull-down circuit 530, the clamp control signal DLCMP and the voltage of the data line DL may be pulled down to the reference ground voltage VSS. Meanwhile, the feedback voltage control signal DLD equals the reference ground voltage VSS, while the feedback voltage VFB equals the power supply voltage VCC. The transistors MP2 and MP3 are in a turned-off state (i.e., the driving control element 521 is disabled).

During the pre-charge period TPSA of the data sensing operation, the sensing enable signal SAEN may be pulled down to a logic low level. At a time point T1, at the beginning of the pre-charge period TPSA, the voltage VDL on the data line DL has a relatively low voltage value; therefore, the buffer 523 may correspondingly generate the feedback voltage control signal DLD with a logic low level. As such, the pre-charge control signal generating circuit pmay generate the pre-charge control signal PREQ that also has a logic low level according to the feedback voltage control signal DLD and the sensing enable signal SAEN, both at a logic low level. Further, the first pre-charge circuit 510 provides the power supply voltage VCC to the sensing voltage node N_{VSA} according to the sensing enable signal SAEN at a low logic level.

During the initial pre-charge period TP1, the transistor MP3 may be turned on according to the pre-charge control signal PREQ with a logic low level. The clamp control signal DLCMP is then pulled up to the power supply voltage VCC. As a result, the power supply voltage VCC from the sensing voltage node N_{VSA} is provided to the data line DL through the clamp circuit 540. This raises the voltage VDL on the data line DL.

At a time point T2, the voltage VDL on the data line DL is raised to the trigger voltage DLTRIG. Afterwards, at a time point T3, the feedback voltage control signal DLD generated by the buffer 523 changes to a logic high level. The pre-charge control signal generating circuit 550 correspondingly changes the generated pre-charge control signal PREQ to a logic high level, causing the transistor MP3 of the driving control element 521 to be turned off. At the same time, the feedback voltage generating element 522 may provide the feedback voltage VFB at a logic low level to the control terminal of the transistor MP2 of the driving control element 521. Therefore, the transistor MP2 may be turned on, causing the voltage value of the clamp control signal DLCMP to equal to or approach the reference voltage SAVREF, and the slope of the voltage rise on the data line DL is thereby decreased.

In this embodiment, when the transistor MN1 is turned on according to the selection signal Y, the global bit line GBL of the memory cell MC and the data line DL are conducted and then raised simultaneously to a voltage value, for example, about 0.8V.

The current-to-voltage converter 500 may convert the current read from the selected memory unit MC into the sensing voltage signal VSA and output it to a sensing amplifier (which includes a comparator). The time difference between the time point T2 and the time point T3 corresponds to the delay from the input to the output of the buffer 523. This delay can be used to adjust the timing when PREQ changes to a logic high level. Specifically, the voltage VDL on the data line DL may be shifted from the preset voltage value according to the state of the threshold voltage of the memory cell MC. The voltage V52 represents the voltage VDL on the data line DL connected to the reference memory cell. If the memory cell MC is a programmed memory cell, the voltage VDL may be shifted upward to voltage V51. If the memory cell MC is an erased memory cell, the voltage VDL may shift downward to the voltage V53. Based on the variation of the voltage VDL on the data line DL, the sensing voltage signal VSA may also exhibit a corresponding variation.

In some embodiments, the above current-to-voltage converter 100, 200, or 500 may be configured to couple to each data line DL coupled to normal memory cells for storing data, without coupling to the data lines coupled to reference memory cells used to provide reference read voltages. This reduces the size of the memory device. In other words, when the memory device has N data lines DL coupled to normal memory cells, N current-to-voltage converters 100, 200, or 500 of the disclosure are configured. That is, the feedback voltage of each current-to-voltage converter is generated independently according to the corresponding data line DL to which it is coupled. However, the disclosure is not limited thereto.

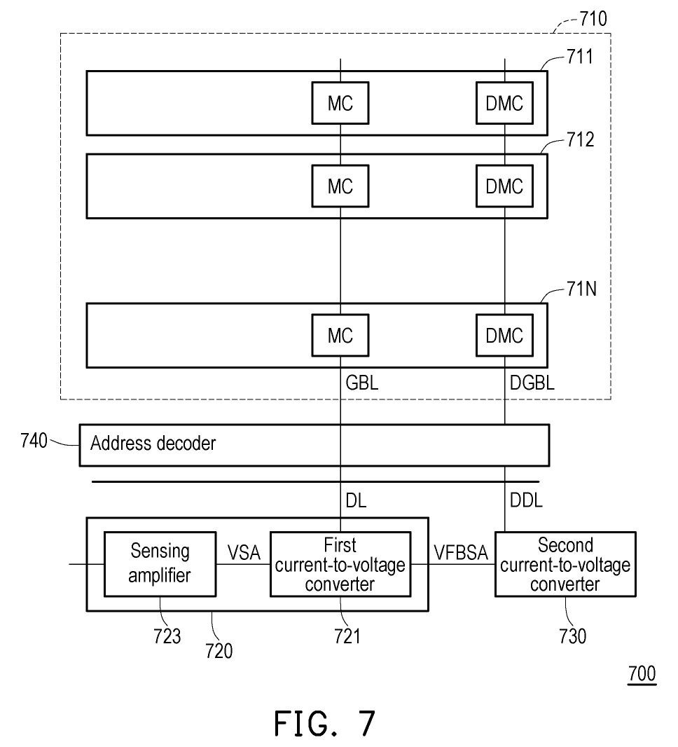

With reference to FIG. 7, a memory device 700 of an embodiment of the disclosure includes a memory cell array 710 composed of a plurality of memory cell rows 711 to 71N, a sensing amplifier group 720, a second current-to-voltage converter 730, and an address decoder 740. The sensing amplifier group 720 includes a plurality of sensing amplifiers 723 and a plurality of first current-to-voltage converters 721. The memory device 700 may be a NOR flash memory device.

In this embodiment, the memory cell array 710 includes a plurality of dummy memory cells DMC coupled to a dummy global bit line DGBL. The dummy global bit line DGBL may be coupled to a dummy data line DDL through the address decoder 740. The second current-to-voltage converter 730 is coupled to the dummy data line DDL and is configured to provide a common feedback voltage VFBSA to these first current-to-voltage converters 721.

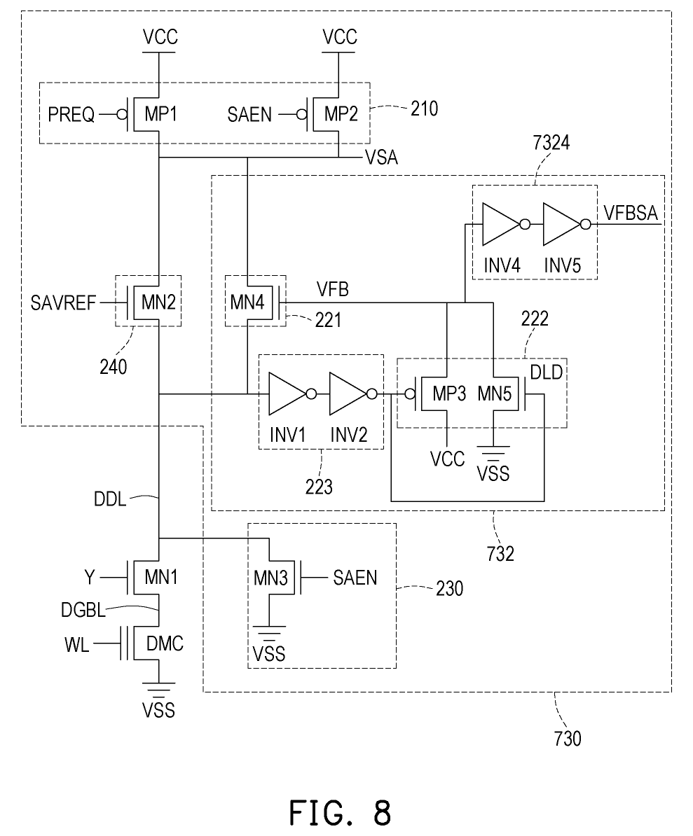

As shown in FIG. 8, the second current-to-voltage converter 730 is similar to the current-to-voltage converters 200 and 500, with the difference being that the second pre-charge circuit 732 of the second current-to-voltage converter 730 further includes an output buffer 7324. The output buffer 7324 is coupled to the feedback voltage generating element 222 and is configured to generate the common feedback voltage VFBSA based on the feedback voltage VFB generated according to the voltage on the dummy data line DDL. The output buffer 7324 may include inverters INV4 and INV5.

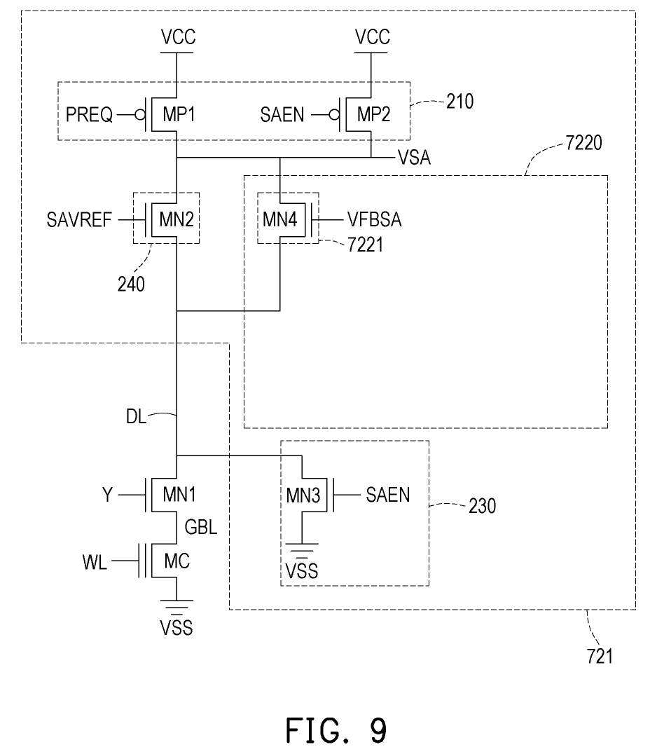

As shown in FIG. 9, each first current-to-voltage converter 721 is coupled to the normal memory cell MC for storing data via the data line DL and the global bit lines GBL. Each first current-to-voltage converter 721 is similar to the current-to-voltage converters 200 and 500, with the difference being that a second pre-charge circuit 7220 of the first current-to-voltage converter 721 is only composed of a driving control element 7221. The driving control element 7221 is controlled by the common feedback voltage VFBSA, so that a size of the sensing amplifier group 720 is reduced.

Regarding the details of the first current-to-voltage converter 721 and the second current-to-voltage converter 730, please refer to the previously mentioned embodiments, and description thereof is not repeated herein. The key point is that in this embodiment, the common feedback voltage VFBSA generated by a single second current-to-voltage converter 730 may be provided to plurality of first current-to-voltage converters 721 in the sensing amplifier group 720.

Based on the above, in the memory device 700, an overall layout area of the first current-to-voltage converter 721 and the second current-to-voltage converter 730 may be effectively reduced. This not only saves circuit size but also reduces power consumption generated during data sensing operations, so the requirements for green semiconductors are satisfied.

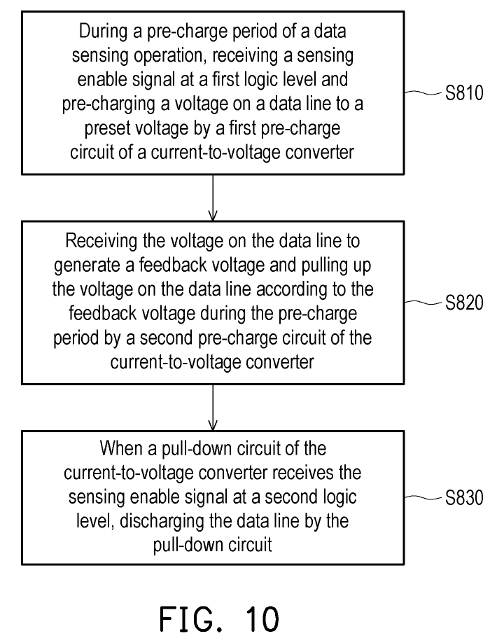

The following describes a data line pre-charge method in the embodiments of the disclosure with reference to FIG. 10. In step S810, during the pre-charge period of a data sensing operation, a sensing enable signal at a first logic level is received through a first pre-charge circuit of a current-to-voltage converter, and a voltage on the data line is pre-charged to a preset voltage. In step S820, the voltage on the data line is received through a second pre-charge circuit of the current-to-voltage converter to generate a feedback voltage, and the voltage on the data line is pulled up based on the feedback voltage during the pre-charge period. In step S830, when a pull-down circuit of the current-to-voltage converter receives the sensing enable signal at a second logic level, the data line is discharged by the pull-down circuit. For details of the operations in the above steps, please refer to the previously mentioned embodiments, and description thereof is not repeated herein.

In view of the foregoing, according to the current-to-voltage converter of the disclosure, the time required for pre-charging the data line may be reduced, so that the read or verification operation time of the memory device is shortened. In order to improve the product lifetime of the memory device, the current-to-voltage converter of this disclosure is also configured to detect the voltage of the data line and automatically stop pre-charging the data line. Further, in an embodiment, in order to reduce the size of the memory device, the current-to-voltage converter of the disclosure may be coupled only to a normal memory cell for storing data, but not to a reference memory cell for providing a reference read voltage. Further, in another embodiment, in order to reduce the size of the memory device, the second current-to-voltage converter for outputting the common feedback voltage and the first current-to-voltage converter for receiving the common feedback voltage may be configured. The second current-to-voltage converter is coupled to a small portion of the data lines, and the first current-to-voltage converter is coupled to the remaining data lines.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A current-to-voltage converter, comprising:
a first pre-charge circuit coupled to a data line and configured to pre-charge a voltage on the data line to a preset voltage according to a sensing enable signal at a first logic level during a pre-charge period of a data sensing operation;
a second pre-charge circuit coupled to the data line and configured to generate a feedback voltage according to the voltage on the data line and pull up the voltage on the data line according to the feedback voltage during the pre-charge period; and
a pull-down circuit coupled to the data line and configured to discharge the data line according to the sensing enable signal at a second logic level,
wherein the data line is coupled to a memory cell.

2. The current-to-voltage converter according to claim 1, further comprising:
a clamp circuit coupled to the first pre-charge circuit, the second pre-charge circuit, and the data line and configured to output a sensing voltage signal at a sensing voltage node between the clamp circuit and the first pre-charge circuit.

3. The current-to-voltage converter according to claim 1, wherein the second pre-charge circuit is configured to provide a pre-charge speed greater than a pre-charge speed provided by the first pre-charge circuit during the pre-charge period.

4. The current-to-voltage converter according to claim 2, wherein the second pre-charge circuit comprises a buffer and a feedback voltage generating element, the buffer is configured to generate a feedback voltage control signal according to the voltage on the data line, the feedback voltage generating element generates the feedback voltage according to the feedback voltage control signal, and the current-to-voltage converter further comprises:
a pre-charge control signal generating circuit configured to perform a logical operation on the feedback voltage control signal and the sensing enable signal to generate a pre-charge control signal.

5. The current-to-voltage converter according to claim 4, wherein the first pre-charge circuit comprises:
a first transistor coupled between a power supply voltage and the sensing voltage node and controlled by the pre-charge control signal; and
a second transistor coupled between the power supply voltage and the sensing voltage node and controlled by the sensing enable signal,
wherein the clamp circuit and the first transistor are coupled in series between the power supply voltage and the data line, and the clamp circuit is controlled by a reference voltage.

6. The current-to-voltage converter according to claim 2, wherein the second pre-charge circuit comprises:
a driving control element coupled in parallel with the clamp circuit between the sensing voltage node and the data line and controlled by the feedback voltage; and
a feedback voltage generating element controlled by the voltage on the data line and generating the feedback voltage according to a power supply voltage and a reference ground voltage.

7. The current-to-voltage converter according to claim 6, wherein the feedback voltage generating element comprises:
a third transistor receiving the power supply voltage and controlled by the voltage on the data line to generate the feedback voltage; and
a fourth transistor receiving the reference ground voltage and controlled by the voltage on the data line to generate the feedback voltage.

8. The current-to-voltage converter according to claim 4, wherein
the first pre-charge circuit comprises a first transistor coupled between a power supply voltage and the sensing voltage node and controlled by the sensing enable signal,
the second pre-charge circuit further comprises a driving control element, and the driving control element provides a clamp control signal to the clamp circuit according to the feedback voltage and the pre-charge control signal,
wherein the clamp circuit and the first transistor are coupled in series between the power supply voltage and the data line, and the clamp circuit is controlled by the clamp control signal.

9. The current-to-voltage converter according to claim 8, wherein the driving control element comprises:
a second transistor receiving a reference voltage and controlled by the feedback voltage to provide the clamp control signal to the clamp circuit; and
a third transistor receiving the power supply voltage and controlled by the pre-charge control signal to provide the clamp control signal to the clamp circuit.

10. The current-to-voltage converter according to claim 9, wherein the reference voltage is less than the power supply voltage.

11. The current-to-voltage converter according to claim 9, wherein the feedback voltage generating element comprises:
an inverter configured to invert the feedback voltage control signal to generate the feedback voltage.

12. The current-to-voltage converter according to claim 9, wherein the pull-down circuit comprises:
a fourth transistor coupled between the data line and a reference ground voltage and controlled by the sensing enable signal; and
a fifth transistor coupled between a control terminal of the clamp circuit and the reference ground voltage and controlled by the sensing enable signal.

13. A data line pre-charge method, comprising:
receiving a sensing enable signal at a first logic level and pre-charging a voltage on the data line to a preset voltage by a first pre-charge circuit during a pre-charge period of a data sensing operation;
receiving the voltage on the data line to generate a feedback voltage and pulling up the voltage on the data line according to the feedback voltage during the pre-charge period by a second pre-charge circuit; and
discharging the data line by a pull-down circuit when the sensing enable signal is at a second logic level.

14. The data line pre-charge method according to claim 13, further comprising:
causing the second pre-charge circuit to stop pulling up the voltage on the data line by the feedback voltage when the voltage on the data line rises to a trigger voltage.

15. The data line pre-charge method according to claim 13, further comprising:
performing a logical operation on the voltage on the data line and the sensing enable signal to generate a pre-charge control signal;
clamping the voltage on the data line to be not greater than the preset voltage by a clamp circuit controlled by a reference voltage during the pre-charge period;
controlling the first pre-charge circuit to provide a power supply voltage to a sensing voltage node according to the pre-charge control signal, wherein the sensing voltage node is between the clamp circuit and the first pre-charge circuit; and
outputting a sensing voltage signal at the sensing voltage node after the pre-charge period.

16. The data line pre-charge method according to claim 13, further comprising:
performing a logical operation on the voltage on the data line and the sensing enable signal to generate a pre-charge control signal;
clamping the voltage on the data line to be not greater than the preset voltage by a clamp circuit controlled by a clamp control signal during the pre-charge period, wherein the clamp control signal is generated according to the feedback voltage and the pre-charge control signal; and
outputting a sensing voltage signal at a sensing voltage node between the clamp circuit and the first pre-charge circuit after the pre-charge period.

17. A memory device, comprising:
a memory cell array comprising a plurality of dummy memory cells and a plurality of normal memory cells, the dummy memory cells are coupled to a dummy global bit line coupled to a dummy data line, and the normal memory cells are coupled to a plurality of global bit lines, and each of the global bit lines is coupled to a data line;
a plurality of first current-voltage converters, wherein each of the first current-voltage converters is coupled to the data line and controlled by a common feedback voltage; and
a second current-to-voltage converter, comprising:
a first pre-charge circuit coupled to the dummy data line and configured to pre-charge a voltage on the dummy data line to a preset voltage according to a sensing enable signal at a first logic level during a pre-charge period of a data sensing operation;
a second pre-charge circuit coupled to the dummy data line, configured to generate a feedback voltage according to the voltage on the dummy data line, generate the common feedback voltage according to the feedback voltage, and pull up the voltage on the dummy data line according to the feedback voltage during the pre-charge period; and
a pull-down circuit coupled to the dummy data line and configured to discharge the dummy data line according to the sensing enable signal at a second logic level.

18. The memory device according to claim 17, wherein the second pre-charge circuit comprises:
a buffer configured to generate a feedback voltage control signal according to the voltage on the dummy data line;
a feedback voltage generating element generating the feedback voltage according to the feedback voltage control signal; and
an output buffer coupled to the feedback voltage generating element and configured to generate the common feedback voltage according to the feedback voltage.

19. The memory device according to claim 17, wherein each of the first current-to-voltage converters comprises:
a third pre-charge circuit coupled to the data line and configured to pre-charge the voltage on the data line to the preset voltage according to the sensing enable signal at the first logic level during the pre-charge period; and
a fourth pre-charge circuit coupled to the data line and configured to pull up the voltage on the data line according to the common feedback voltage during the pre-charge period.

20. The memory device according to claim 19, wherein the fourth pre-charge circuit is formed by a driving control element.
